(19) United States
(12) Patent Application Publication
(10) Pub. No.: US 2009/0212422 A1
(43) Pub. Date: Aug. 27, 2009

(54) JOINT RELIABILITY OF SOLDER JOINT BETWEEN Sn-yAg SOLDER AND Ni-P UNDER BUMP METALLIC LAYER BY COBALT ADDITION

(75) Inventors: Hyuck Mo LEE, Daejeon (KR); Moon Gi CHO, Daejeon (KR); Dong Hoon KIM, Daejeon (KR)

Correspondence Address: BARDMESSER LAW GROUP, P.C., 1025 CONNECTICUT AVENUE, N.W., SUITE 1000, WASHINGTON, DC, 20006, US

(73) Assignee: KOREA ADVANCED INSTITUTE OF SCIENCE AND TECHNOLOGY, Daejeon (KR)

(21) Appl. No.: 12/182,180

(22) Filed: Jul. 30, 2008

(30) Foreign Application Priority Data
Feb. 26, 2008 (KR) 10-2008-0017524

(51) Int. Cl. H01L 23/488; B32B 15/00

(52) U.S. Cl. 257/737; 428/615; 257/E23.023

(57) ABSTRACT

An improvement of joint reliability between Sn-yAg (0≦y≦4.0) solder and Ni—P under-bump metallic layers is achieved by cobalt (Co) addition. A solder joint with improved joint reliability is formed between a solder part of an electronic packaging and an under-bump metallic (UBM) layer, which has a specific structure comprising Sn-yAg-xCo (0.02≦x≦0.1, 0≦y≦4.0) alloy solder containing cobalt (Co) ingredient bonded to a Ni—P UBM. Also, a solder joint with a joint structure comprising Sn-yAg-xCo (0.02≦x≦0.1, 0≦y≦4.0) alloy solder with addition of Co ingredient and Ni—P UBM is formed, which is inserted between a PCB substrate and a silicon chip to join the same.

### CROSS-REFERENCE TO RELATED APPLICATIONS

The present application claims priority to Korean Patent Application No. 10-2008-0017524, filed Feb. 26, 2008, which is incorporated herein by reference in its entirety.

### BACKGROUND OF THE INVENTION

1. Field of the Invention

The present invention relates to improvement of joint reliability between Sn-yAg (0≦y≦4.0) solder and Ni—P under-bump metallic layers (“UBMs”) by adding cobalt (Co) addition, and more particularly, to an improved solder joint structure with high joint reliability between Sn-yAg (0≦y≦4.0) solder and Ni—P under-bump metallic layer by Co addition, which is accomplished by use of Sn-yAg (0≦y≦4.0) alloy solder with the addition of Co as one of the elements of the solder joint.

2. Description of the Related Art

Conventional solder alloys employed in solder joints are well known to comprise binary and/or ternary alloy compositions such as Sn—Ag, Sn—Cu, Sn—Ag—Cu, etc.

When a conventional Sn-yAg (0≦y≦4.0) solder is bonded to a Ni—P UBM to generate an intermetallic compound, the compound be released from an interface between the solder and the UBM, and floats into the solder. This is referred to as “spalling” of the compound. As a result, the mechanical properties at the interface between the solder and the UBM coated with the intermetallic compound can deteriorate.

As noted above, lead-free solders used in the solder joints generally comprise binary and/or ternary alloy compositions such as Sn—Ag, Sn—Cu, Sn—Ag—Cu, etc. When a conventional Sn-yAg (0≦y≦4.0) solder is combined with (or bonded to) a Ni—P UBM, intermetallic compounds (often referred to as “IMCs”) are generated at an interface between the solder and UBM by chemical reaction between the metal ingredients contained in the solder and the UBM, respectively. Although IMCs generated at the interface are necessarily used to form solder joints between electronic parts, the IMCs with reduced weight cause a degradation of mechanical properties and thus require appropriate control thereof. In particular, Ni₃Sn₄ as one of IMCs generated by the chemical reaction between Sn-yAg (0≦y≦4.0) solder and Ni—P UBM cannot continuously adhere to the interface between the liquid solder and the UBM, but floats into the solder, that is, causes spalling of the compound. Such floated IMC, that is, Ni₃Sn₄, reduces bonding properties at the interface between the liquid solder and the UBM and, when the solder joint is under specific stress conditions, the floated IMC serves as a path for crack propagation. Therefore, it is very important to prevent spalling of Ni₃Sn₄ in order to improve reliability of a solder joint.

Many publications describe the problems in using solder for bonding electronic components, for example: Y. C. Sohn, Jin Yu, S. K. Kang, D. Y. Shih, and T. Y. Lee, J. Mater. Res., 19(8), 2428-2436 (2004); Chi-Won Hwang, and Katsuaki Suganuma, J. Mater. Res., 18(11) 2540-2543 (2003); Ja-Myeong Koo, and Seung-Boo Jung, Micro. Eng. 82(2005) 569-574, disclose that the intermetallic compound Ni₃Sn₄ is generated in the form of “needles” at the interface between Sn-yAg (0≦y≦4.0) solder and Ni—P UBM by reaction of liquid Sn and solid Ni when they are joined together. Such needle form provides a passage for the liquid Sn to penetrate into the UBM even after generation of the intermetallic compound. Continuous penetration of the liquid Sn increases P content in amorphous Ni—P, induces formation of a Ni—Sn—P layer between Ni₃Sn₄ and Ni—P portions and causes spalling between the Ni—Sn—P layer and Ni₃Sn₄. This causes a deterioration of mechanical properties at the interface between the solder and the intermetallic compound adhered on the UBM.

Accordingly, there is a need in the art for a better solder composition that does not suffer from the above problems.

### SUMMARY OF THE INVENTION

Accordingly, the present invention is directed to solve problems of conventional arts as described above. An object of the present invention is to inhibit spalling of an intermetallic compound Ni₃Sn₄ generated at an interface between Sn-yAg (0≦y≦4.0) solder and Ni—P UBM when they are combined (or bonded) together, by a process that comprises: adding cobalt (Co) in the range from 0.02 to 0.1% by weight (“wt. %”) to a Sn-yAg (0≦y≦4.0) solder composition; loading the mixture into a liquid crystal tube then sealing the tube; placing the sealed tube in a furnace at 900 to 1,000° C. for over 24 hours to completely fuse the mixture; mechanically agitating the fused mixture for 5 to 10 minutes to prepare a homogeneous solution of Sn-yAg-xCo (0.02≦x≦0.1, 0≦y≦4.0) alloy solder; forming the solution into a solid product with specific shape; and bonding the solid product to the Ni—P UBM.

In order to confirm interfacial reaction between alloy solder and UBM, two types of commonly used UBMs were used: (1) a large-sized UBM prepared by electroless plating of a 6 mm×6 mm Si chip with Ni—P so as to monitor the interfacial reaction between the alloy solder and the UBM in an experiment involving large dimensions; and (2) a PCB substrate with opening size of 680 μm and diameter of a solder ball of 720 μm. This was done in order to determine whether Co addition can be effectively applied to industrial manufacturing processes (hereinafter, referred to as “industrial process”). Alternatively, the interfacial reaction was observed depending on different reflow times together with a desired composition of the alloy solder. From results of these three experiments, it was determined that Co addition can preferably improve solder reliability between Sn-yAg (0≦y≦4.0) solder and Ni—P UBM.

During typical formation of a joint between Sn-yAg (0≦y≦4. 0) solder and Ni—P UBM, the intermetallic compound Ni₃Sn₄ caused deterioration of mechanical properties due to spalling thereof, that is, floating of the intermetallic compound into a liquid solder portion of the solder.

The present invention provides a novel alloy solder with a specific composition to exhibit improved properties of a solder joint between Sn-yAg (0≦y≦4.0) solder and a Ni—P under-bump metallic layer, which comprises a typical Sn-yAg (0≦y≦4.0) solder and 0.02 to 0.1 wt. % of Co compound to the typical solder, which is effective in inhibiting spalling of a specific intermetallic compound Ni₃Sn₄ generated during formation of a solder joint at the interface between the alloy solder and the UBM such as cracking and/or fracturing. The alloy solder can reduce an amount of the intermetallic compound and, at the same time, prevent breaking of the solder joint and/or mechanical weakness caused by the intermetallic compound.

In order to enhance reliability of solder joints employed in electronic packaging applications, the present invention suggests a preferred composition of Sn-yAg (0≦y≦4.0) alloy solder as one of elements for a solder joint.

More particularly, in order to overcome various problems of conventional methods described above, the present invention provides a novel alloy solder with a composition represented by Sn-yAg-xCo (0.02≦x≦0.1, 0≦y≦4.0), which is manufactured by adding cobalt element in the range from 0.02 to 0.1 wt. % to Sn-yAg (0≦y≦4.0) alloy solder, so as to prevent spalling of an intermetallic compound in the solder, and generate the intermetallic compound Ni₃Sn₄ at the interface between Sn-yAg (0≦y≦4.0) solder and Ni—P UBM to inhibit additional chemical reaction between liquid solder portion and solid UBM, and to enhance bonding properties thereof, thereby improving mechanical reliability of a solder joint.

With regard to formation of a solder joint between a solder and a UBM in an electronic package, according to one embodiment of the present invention, the solder comprises Sn-yAg-xCo (0.02≦x≦0.1, 0≦y≦4.0) alloy solder with added Co the UBM comprises a Ni—P under-bump metallic layer, and the solder joint has a specific structure of the solder bonded to the Ni—P UBM with improved joint reliability.

The alloy solder may include 0.02 to 0.1 wt. % of cobalt ingredient. y, as noted earlier, ranges from 0 to 4.0, more preferably, from 1 to 4.0, more preferably still, from 2 to 4.0, more preferably still, from 3.5 to 4.0. The Co content should preferably range up to 0.1%, and at most no higher than about 0.2%. With higher Co content (e.g., 0.4% to 0.7% wt. % Co), other undesirable effects may occur, such as deterioration of mechanical properties, or formation of compounds other than Ni₃Sn₄ at the interface.

Improvement of joint reliability can be achieved by forming a specific intermetallic compound Ni₃Sn₄ at the interface between Sn-yAg (0≦y≦4.0) alloy solder containing Co ingredient and Ni—P UBM, which does not spall from the interface.

An aspect of the present invention is to provide a solder joint formed between Sn-yAg-xCo (0.02≦x≦0.1, 0≦y≦4.0) alloy solder with added Co ingredient and Ni—P UBM, which has improved joint reliability when the solder joint is inserted between a PCB substrate and a silicon chip to mount the chip on the PCB.

Alternatively, the solder joint may be employed to form single or multiple joints between PCB substrates and/or between silicon chips, respectively, with improved joint reliability.

Additional features and advantages of the invention will be set forth in the description that follows, and in part will be apparent from the description, or may be learned by practice of the invention. The advantages of the invention will be realized and attained by the structure particularly pointed out in the written description and claims hereof as well as the appended drawings.

It is to be understood that both the foregoing general description and the following detailed description are exemplary and explanatory and are intended to provide further explanation of the invention as claimed.

### BRIEF DESCRIPTION OF THE ATTACHED DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a schematic view showing a solder joint used to combine together electronic parts;

FIG. 2 shows photographs of a cross-sectional side of Sn-3.5Ag-xCo solder and Ni—P UBM treated by quenching after soldering at 250° C. for 10 minutes;

FIG. 3 shows photographs of a cross-sectional side of Sn-3.5Ag-xCo solder and Ni—P UBM after deep etching;

FIG. 4 shows photographs of reaction between ENIG PCB substrate and Sn-3.5Ag-xCo solder ball;

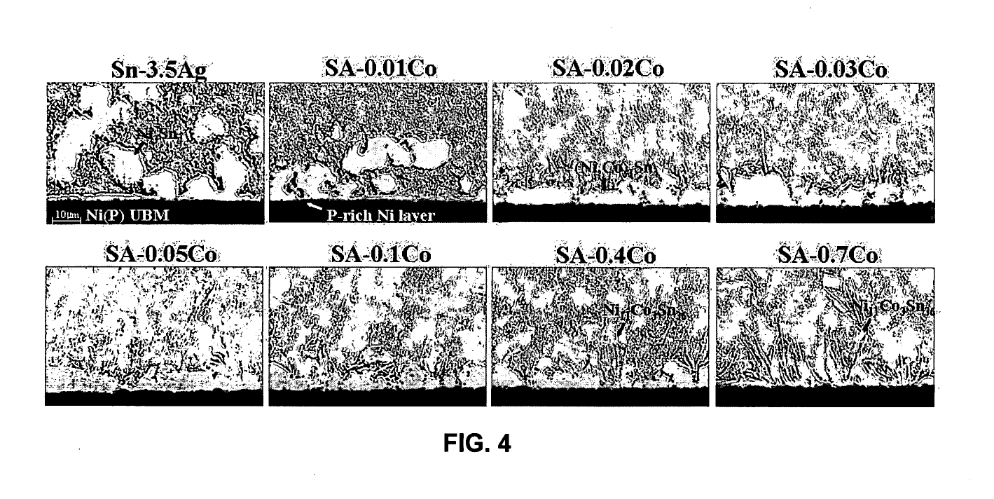

FIG. 5 shows photographs of variations of the interfacial reaction shown in FIG. 4 according to reaction time; and

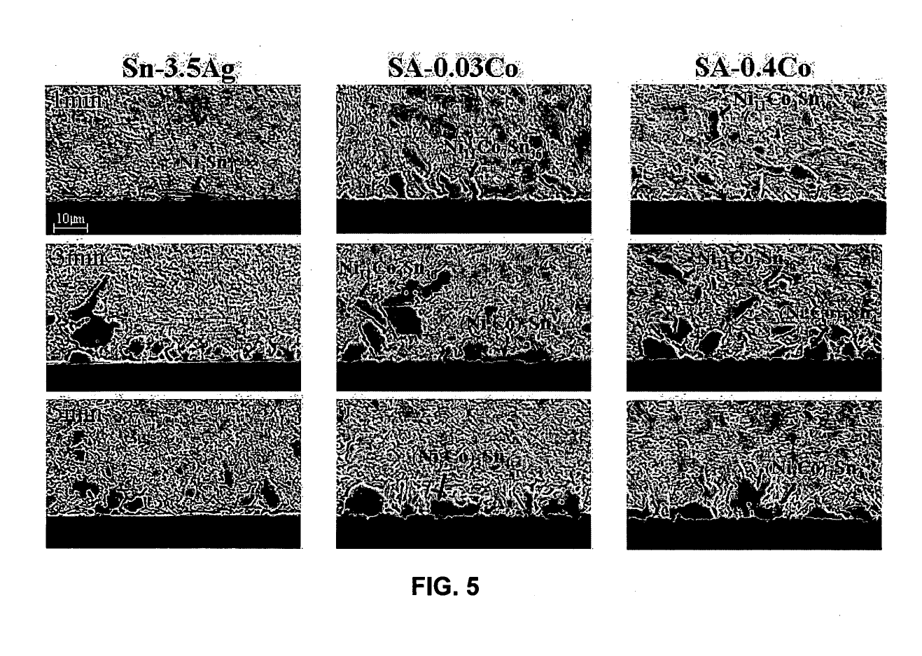

FIG. 6 shows photographs of cross-sectional sides of Sn-0.02Co solder and Ni—P UBM, as well as Sn-4.0Ag-0.02Co solder and Ni—P UBM treated as described in Example 2, respectively.

FIG. 7 shows photographs of a multi-layer PCB using the solder joints of the present invention.

FIG. 8 shows a photograph of multiple semiconductor chips in a sandwich structure, joined using the solder joints of the present invention.

### DETAILED DESCRIPTION OF THE PREFERRED EMBODIMENTS

Reference will now be made in detail to the embodiments of the present invention, examples of which are illustrated in the accompanying drawings.

The present invention proposes a novel alloy solder with a specific composition in order to attain improved properties of a solder joint between Sn-yAg (0≦y≦4.0) solder and a Ni—P under-bump metallic layer. The proposed solder composition is represented by Sn-yAg-xCo (0.02≦x≦0.1, 0≦y≦4.0) that includes 0.02 to 0.1% by weight of cobalt (Co), as well as Sn-yAg (0≦y≦4.0) solder. This composition inhibits spalling of an intermetallic compound Ni₃Sn₄ generated during formation of a joint at an interface between the alloy solder and the under-bump metallic layer. This reduces the amount of the intermetallic compound, and, at the same time, prevents breaking, cracking and/or fracturing of the solder joint and/or mechanical weakness caused by the intermetallic compound.

Based on the above advantageous features, the present invention can provide a solder joint with improved reliability, compared to conventional solder joints, by preventing continuous penetration of liquid Sn into the solder joint, and, in turn, inhibiting additional formation of Ni₃Sn₄. The present invention thus proposes a novel solder composition by adding a small amount of Cobalt to a typical Sn-yAg (0≦y≦4.0) binary composition.

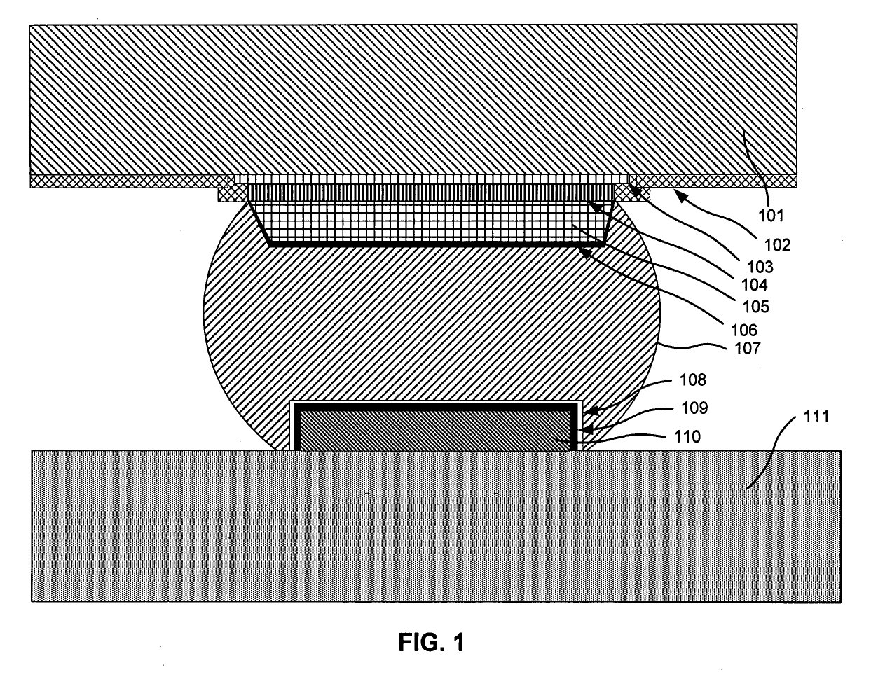

FIG. 1 illustrates one embodiment of the present invention. As shown in FIG. 1, a solder bump 107 is sandwiched between a silicon chip 101 and a printed circuit board (PCB) 111. The silicon chip 101 has a passivation layer 102 thereon. Also, a sputtered titanium tungsten (TiW) adhesion layer is present on the silicon chip. Adhesion layer 103 is present on a silicon chip. A sputtered copper or aluminum seed layer for electroless Ni—P placing is present on the adhesion layer 103. An electroless Ni—P layer 104 is on the seed layer 103, as shown in FIG. 1. A thin immersion gold layer 106 covers the electroless Ni—P layer 105.

Collectively, the layers 104, 105 and 106 form what is referred to as the under-bump metallic layer (UBM), which collectively comprises titanium tungsten/copper/nickel-phosphorous/gold (i.e., TiW/Cu/Ni—P/Au).

On the PCB 111 side, the PCB includes an electroplated copper layer 110, an electroless Ni—P layer 109, and an immersion gold layer 108. The electroless Ni—P layer 109 serves as a diffusion barrier, and an immersion gold (Au) layer serves as a wetting layer. The present invention describes formation of solder joints between electronic parts in electronic packaging applications by adopting Sn-yAg (0≦y≦4.0 preferably 3.5≦y≦4.0) solders and Ni—P UBMs. The Sn-yAg (0≦y≦4.0) solders are mostly formed of solder alloys and, in recent years, usually comprise lead-free solders in view of environmental problems.

According to one embodiment of the present invention, a solder alloy containing Cobalt is inserted between a PCB substrate and a silicon chip to combine them together with improved joint reliability. If necessary, this solder may be also used to combine together PCB substrates and/or silicon chips, respectively.

The Co-containing solder that is effective to inhibit spalling of Ni₃Sn₄ generated at the interface between the solder and the UBM, according to one embodiment of the present invention, will be described in more detail by the following example with reference to the accompanying drawings.

### EXAMPLE 1

70 mg of solder alloy was placed on a Si chip and reacted on a hot plate heated to 250° C. for 10 minutes, followed by water quenching of the reacted chip. The water quenching process was performed to monitor properties of an interface formed immediately after liquid-solid interfacial reaction, since spalling of IMC occurs during the interfacial reaction between a liquid solder portion and a solid UBM.

Next, an additional experiment was carried out to determine interface properties under the same conditions as those of industrial processes. A PCB substrate and solder balls were used together with a reflow machine in the experiment, and experimental conditions were the same as those for industrial processes. The highest temperature was 250° C. and, after reacting for 1, 3, 5 and/or 10 minutes, the reaction product underwent air cooling.

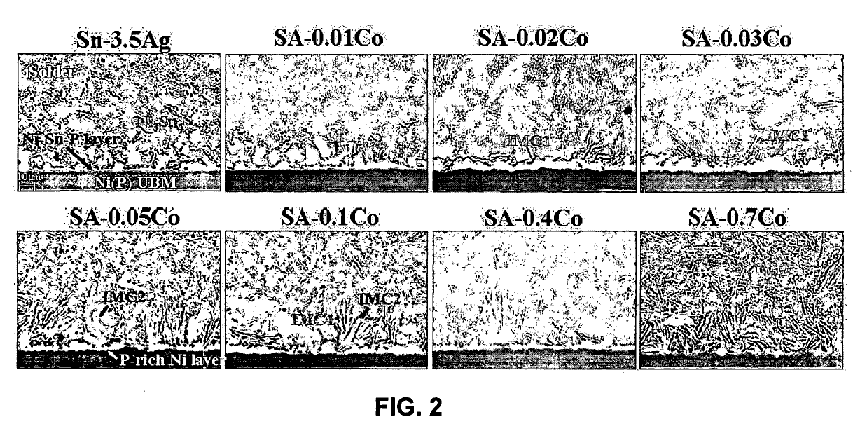

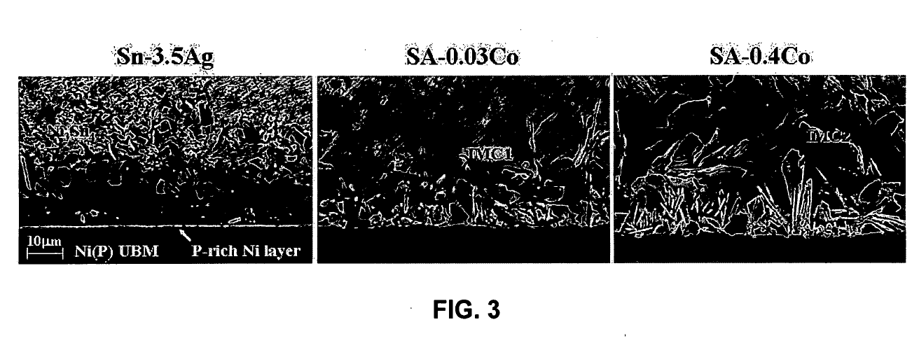

Referring to FIG. 2 which shows results of the above experiment, SA-0.01Co comprising Sn-3.5Ag and 0.01 wt. % of Co ingredient showed that an intermetallic compound Ni₃Sn₄ was released from Ni—P UBM and floated into the liquid solder portion. In contrast, for an alloy solder containing 0.02 to 0.03 wt. % of Co, it was demonstrated that the intermetallic compound generated by interfacial reaction did not float into the liquid solder portion but had adhered stably to the interface. Briefly, it was clearly shown that the addition of Co ingredient can inhibit spalling of the intermetallic compound. This result is even better understood from the photographs showing a cross-sectional side of Sn-3.5Ag-xCo solder and Ni—P UBM after deep etching to remove the solder portion (see FIG. 3).

In order to determine whether the addition of Co ingredient is also effective for industrial processes, an experiment was performed using PCB substrates. From the results of this experiment, it was found that spalling of the intermetallic compound can also be inhibited even when addition of Co ingredient (in the range from 0.02 to 0.1 wt. %) was applied to the industrial processes. For PCB substrates usually employed in an industrial process, the substrates often have gold (Au) deposited surfaces to prevent oxidation of Ni—P and are generally called ENIG (Electroless Ni—P/Immersion Gold).

The interfacially reacting condition described above can be classified into three kinds of conditions, for example: spalling of IMC for Sn-3.5Ag and/or SA-0.01Co (containing 0.01 wt. % of Co ingredient) (in case of ENIG PCB substrate); inhibited spalling of IMC for SA-0.02Co to SA-0.1Co (containing 0.02 to 0.1 wt. % of Co); and variation in morphology of IMC and release of IMC out of the interface for SA-0.4Co and/or SA-0.7Co (containing 0.4 wt. % and/or 0.7 wt. % of Co).

Following this, for each of the above three kinds of alloy solders with selected specific compositions, the interfacial reaction between the alloy solder and UBM was observed with different reflow times. From results of this experiment, it was found that each of the alloy solders showed spalling at the reflow time of 1 minute and/or 3 minutes even though Co was added to the alloy, which is substantially the same as the Sn-3.5Ag solder. However, if the reaction time was over 5 minutes, spalling of IMC was not observed.

Reflowing is usually carried out at the highest practical temperature for 1.5 to 2 minutes during an electronic packaging process, and, if an alloy solder with added Co is applied to the industrial process, spalling of IMC can be desirably inhibited by continuously repeating the same process several times, for example, 3 to 5 times.

Based on the above results, spalling at an interface between solder and UBM dependent on amount of Co to be added is shown in Table 1 below.

TABLE 1
Summary of interfacial reaction

| | Amount of Co addition | | | |
|---|---|---|---|---|
| | 0 to | 0.02 to | | |
| Content | 0.01 wt. % | 0.1 wt. % | 0.4 wt. % | Above 0.7 wt. % |
| Spalling | Yes | None | None | None |

As understood from the above results, with 0 to 0.01 wt. % of Co, the solder showed spalling and had inferior interface properties. In contrast, when the amount of Co to be added ranged from 0.02 to 0.1 wt. %, there was no spalling, thus resulting in improvement of interface properties. Furthermore, the solders with Co addition of 0.4 wt. % and/or above 0.7 wt. % did not exhibit spalling but comprise alternative IMCs with partially different morphologies.

### EXAMPLE 2

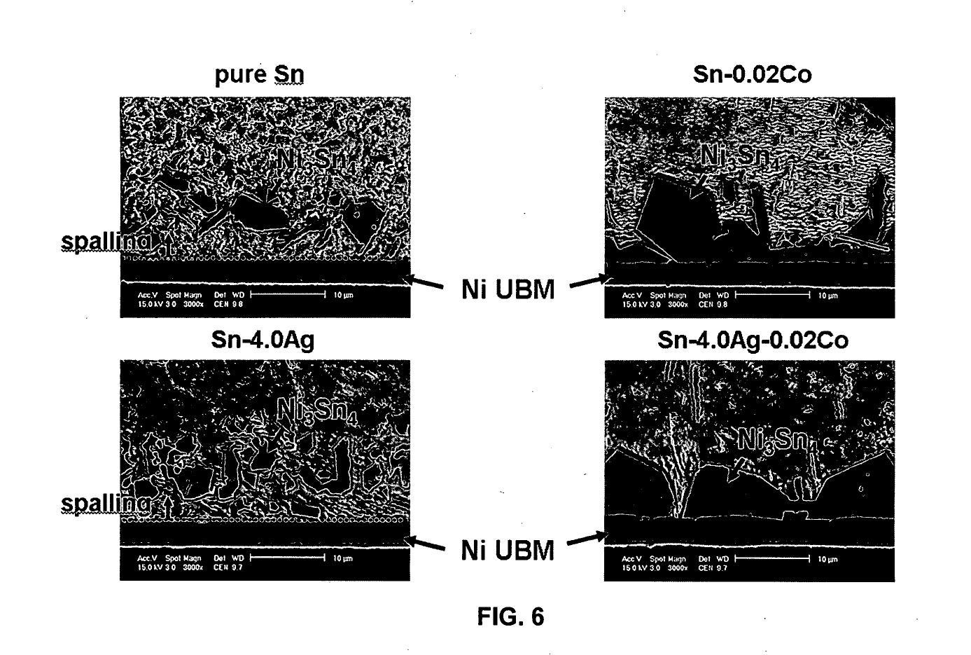

Sn-0.02Co and Sn-4.0Ag-0.02Co were formed by the same procedure described in Example 1, except that pure Sn and Sn-4.0Ag were used as a solders, respectively, an amount of Co was 0.02 wt. % and the reflowing was carried out at 260° C. for 10 minutes. Spalling of each of the resulting products was monitored, and the results are shown in FIG. 6.

Referring to FIG. 6, it was found that even when using the pure Sn solder or Sn-4.0Ag solder instead of Sn-3.5Ag solder, spalling of an intermetallic compound at an interface between the above solder and Ni—P UBM was inhibited by adding Co in an amount ranging from 0.02 wt. % to 0.1 wt. %.

According to one embodiment of the present invention, spalling of IMC during formation of a solder joint is prevented by adding a small amount such as 0.02 to 0.1 wt % of Co to a Sn-yAg (0≦y≦4.0) solder alloy, so that Ni₃Sn₄ generated at the interface between the solder and UBM can inhibit additional chemical reaction of a liquid solder portion with UBM and can enhance joint properties, thereby improving mechanical reliability. Moreover, improvement of joint reliability between Sn-yAg (0≦y≦4.0) solder containing Co and Ni—P UBM can enhance durability and reliability of electronic products.

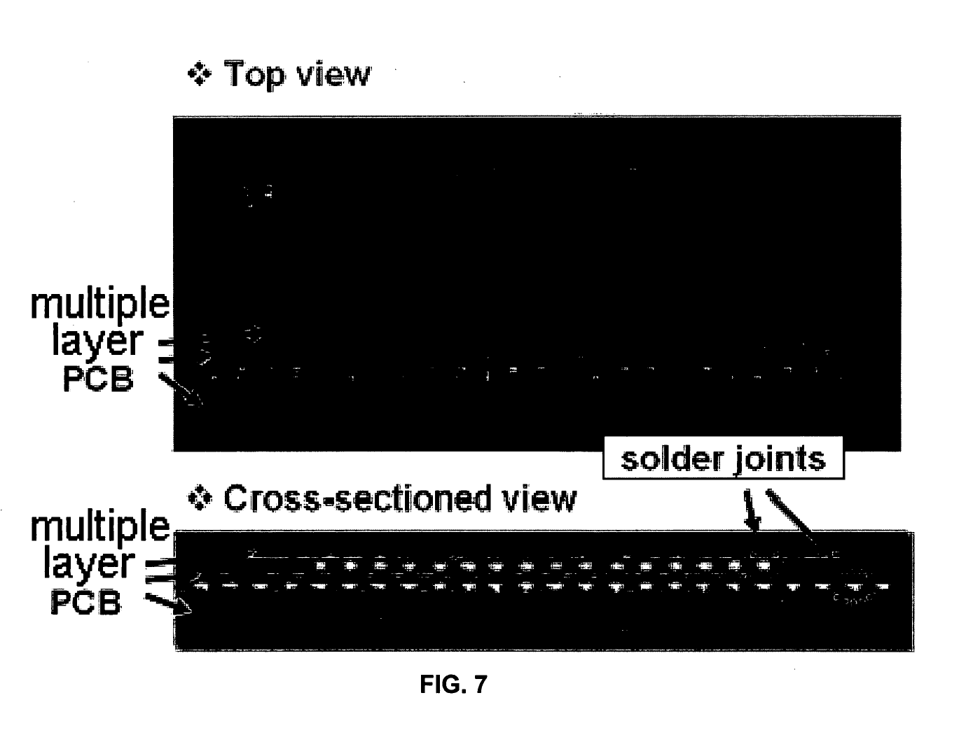

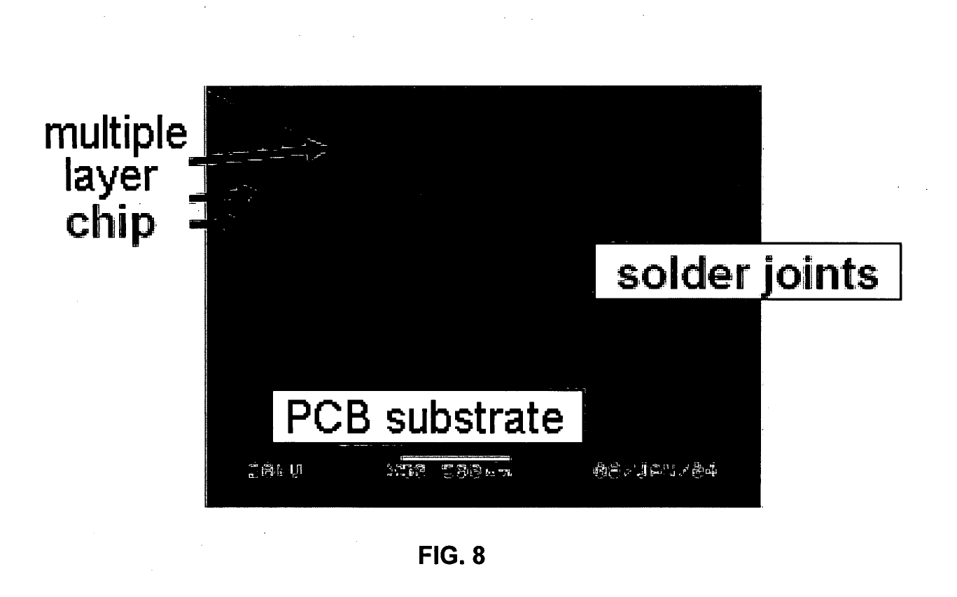

According to another embodiment, FIG. 7 shows photographs of a multi-layer PCB using the solder joints of the present invention. According to another embodiment, FIG. 8 shows a photograph of multiple semiconductor chips in a sandwich structure, joined using the solder joints of the present invention.

Having thus described the different embodiments of the invention, it should be apparent to those skilled in the art that certain advantages of the described method and system have been achieved. It should also be appreciated that various modifications, adaptations, and alternative embodiments thereof may be made within the scope and spirit of the present invention. The invention is further defined by the following claims.

What is claimed is:

1. A solder joint between a solder pad of an electronic package and an under-bump metallic layer, wherein the solder joint comprises:
a structure comprising Sn-yAg-xCo (0.02≦x≦0.2, 0≦y≦4.0) alloy solder;
wherein the Co is added to a Sn-yAg solder joint composition, and wherein the solder joint is bonded to a Ni—P under-bump metallic layer.

2. The solder joint according to claim 1, wherein y ranges from about 1.0 to about 4.0 wt. %.

3. The solder joint according to claim 2, wherein y ranges from about 2.0 to about 4.0 wt. %.

4. The solder joint according to claim 3, wherein y ranges from about 3.5 to about 4.0 wt. %.

5. The solder joint according to claim 1, wherein x ranges from about 0.05 to about 0.15 wt. %.

6. The solder joint according to claim 5, wherein x ranges from about 0.075 to about 0.1 wt. %.

7. The solder joint according to claim 1, wherein Ni₃Sn₄ is formed at an interface between Sn-yAg-xCo and the Ni—P under-bump metallic layer.

8. electronic package with improved solder joint, the structure comprising:
a printed circuit board;
a semiconductor chip;
a solder joint between the printed circuit board and the semiconductor chip, the solder joint comprising a Sn-yAg-xCo (0.02≦x≦0.2, 0≦y≦4.0) alloy solder;
wherein the Co is added to a Sn-yAg solder joint composition, and
wherein the solder joint is bonded to a Ni—P under-bump metallic layer.

9. The solder joint according to claim 8, wherein multiple solder joints of claim 8 are used to join multiple PCB substrates.

10. The solder joint according to claim 8, wherein multiple solder joints of claim 8 are used to join multiple silicon chips.

11. The solder joint according to claim 8, wherein y ranges from about 1.0 to about 4.0 wt. %.

12. The solder joint according to claim 11, wherein y ranges from about 2.0 to about 4.0 wt. %.

13. The solder joint according to claim 12, wherein y ranges from about 3.5 to about 4.0 wt. %.

14. The solder joint according to claim 8, wherein x ranges from about 0.05 to about 0.15 wt. %.

15. The solder joint according to claim 9, wherein x ranges from about 0.075 to about 0.1 wt. %.

16. The solder joint according to claim 8, wherein Ni₃Sn₄ is formed at an interface between Sn-yAg-xCo and the Ni—P under-bump metallic layer.
